(19) United States
(12) Patent Application Publication
(10) Pub. No.: US 2025/0315583 A1
(43) Pub. Date: Oct. 9, 2025

(54) Techniques For Using Machine Learning To Test Integrated Circuit Dies

(71) Applicant: Altera Corporation, San Jose, CA (US)

(72) Inventors: Jalal Mohammad, San Jose, CA (US); Aman Aflaki Beni, San Jose, CA (US)

(73) Assignee: Altera Corporation, San Jose, CA (US)

(21) Appl. No.: 19/238,094

(22) Filed: Jun. 13, 2025

(51) Int. Cl. G06F 30/3323; G06N 20/20

(52) U.S. Cl. CPC G06F 30/3323; G06N 20/20

(57) ABSTRACT

A computing system includes a processor circuit configured to receive test data generated from testing integrated circuit dies in a test flow. The computing system includes a machine learning model that uses the test data generated from the test flow to predict bench results that are indicative of which ones of the integrated circuit dies fail to satisfy a manufacturing protocol when the integrated circuit dies are coupled to circuit boards.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram of a flow chart that includes operations that can be used to incorporate machine learning (ML) models into the manufacturing of integrated circuit (IC) dies.

FIG. 2 is a diagram of a flow chart that includes examples of operations that can be performed to train an ML model for identifying failures in IC dies after manufacturing.

FIG. 3 is a diagram of a flow chart that includes examples of operations that can be performed to identify integrated circuit (IC) dies that fail to satisfy a manufacturing protocol using a trained ML model.

FIG. 4 is a diagram of another flow chart that includes examples of operations that can be performed to identify integrated circuit (IC) dies that fail to satisfy a manufacturing protocol using a trained ML model.

FIG. 5 is a diagram that illustrates an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

Integrated circuit (IC) dies are usually tested prior to operation on customer circuit boards. Bench testing of IC dies that are coupled to customer circuit boards can be used to identify marginal IC dies. In high volume manufacturing (HVM) of transceiver integrated circuit (IC) dies, external loopback transceiver screening may be insufficient to screen marginal IC dies compared to bench testing. Passing units in HVM may fail certain protocols on bench or customer setup. IC dies that pass HVM tests may still show failures on bench testing, indicating a gap in the screening process. Identifying the root cause of these failures and implementing a potential fix is a significant and costly undertaking.

According to some examples disclosed herein, a machine learning (ML) model is provided (e.g., an XGBoost algorithm) that is trained on data from bench failing IC dies that are coupled to circuit boards to predict bench fallout of external loopback testing during the manufacturing process of the IC dies. The ML model utilizes gradient-boosted decision trees and is constructed using HVM sort and class logged parameters in conjunction with bench data, enabling accurate prediction of bench failures of IC dies when the IC dies are coupled to customer circuit boards.

Multiple ML models (e.g., 6 models) can be developed for external loopback testing. When combined, these ML models can predict 100% of bench fallouts. These techniques can be applied to all types of analog and digital circuits. For example, these techniques can be applied to external transceiver loopback testing for transceiver IC dies. Also, these techniques can be used for reliability prediction in digital circuits that are analog in nature, such as static random access memory (SRAM) IC dies.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

Integrated circuit (IC) dies (such as transceiver IC dies) are tested and validated across multiple manufacturing protocols. During bench testing of IC dies (such as transceiver IC dies) that are coupled to customer circuit boards, failures may occur in three manufacturing protocols, Long Range (LR), Very Short Range (VSR), and Chip-to-Module (C2M). These failures may not be effectively screened during sort and class manufacturing steps. According to some examples disclosed herein, ML models are provided that predict bench fallout using sort and class IC die manufacturing data.

According to a specific example, six XGBoost machine learning (ML) models are provided that predict IC die failings from manufacturing test data. The following six XGBoost machine learning (ML) models can be trained using sort and class test data.

1. The first ML model receives sort VSR test input data, and the results of the first ML model are compared to bench VSR protocol results. The input data to the first ML model includes sort test data with 100+ features related to universal extreme external loopback test (UXELT) collected at a temperature of −5° C. The target is a pass/fail status from the bench VSR protocol results.

2. The second ML model receives class VSR test input data, and the results of the second ML model are compared to bench VSR protocol results. The input data to the second ML model includes class test data with 100+ features related to UXELT collected at a temperature of −40° C. The target is a pass/fail status from the bench VSR protocol results.

3. The third ML model receives sort LR test input data, and the results of the third ML model are compared to bench LR protocol results. The input data to the third ML model includes sort test data with 100+ features related to UXELT collected at a temperature of −5° C. The target is a pass/fail status from the bench LR protocol results.

4. The fourth ML model receives class LR test input data, and the results of the fourth ML model are compared to bench LR protocol results. The input data to the fourth ML model includes class test data with 100+ features related to UXELT collected at a temperature of −40° C. The target is a pass/fail status from the bench LR protocol results.

5. The fifth ML model receives sort C2M test input data, and the results of the fifth ML model are compared to bench C2M protocol results. The input data to the fifth ML model includes sort test data with 100+ features related to UXELT collected at a temperature of −5° C. The target is a pass/fail status from the bench C2M protocol results.

6. The sixth ML model receives class C2M test input data, and the results of the sixth ML model are compared to bench C2M protocol results. The input data to the sixth ML model includes class test data with 100+ features related to UXELT collected at a temperature of −40° C. The target is a pass/fail status from the bench C2M protocol results.

These six ML models can be combined in a serial mode to predict 100% of the bench fallouts (i.e., IC dies failing manufacturing protocols) after the manufacturing of the IC dies. A capture rate analysis has shown a significant predictive power, demonstrating a high level of efficacy of identifying failing IC dies after manufacturing.

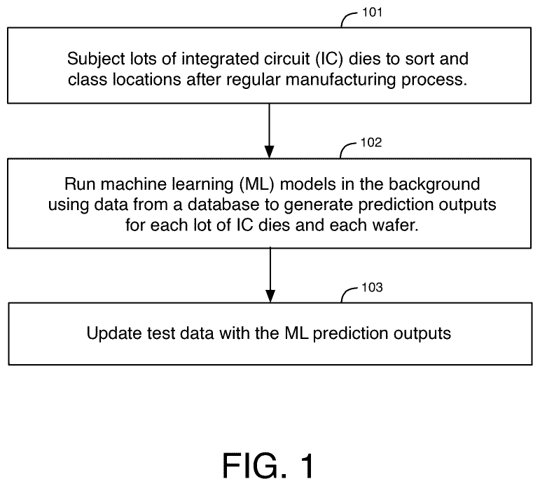

FIG. 1 is a diagram of a flow chart that includes operations that can be performed to incorporate machine learning (ML) models into the manufacturing of integrated circuit (IC) dies. Initially, a regular manufacturing process is performed to manufacture lots of integrated circuit (IC) dies (also referred to herein as integrated circuits (ICs)) from semiconductor wafers. In hold and review operation 101, the lots of the IC dies are subjected to sort and class locations after the regular manufacturing process for the IC dies. In ML automation development operation 102, machine learning (ML) models are run in the background using data accessed from a database to generate prediction outputs for each lot of IC dies and for each semiconductor wafer that the IC dies came from. In output re-scripter tool operation 103, an output re-scripter tool updates test data with the ML prediction outputs. The rejected IC dies can be saved for potential use after a firmware fix to the manufacturing process.

XGBoost, short for Extreme Gradient Boosting, is an advanced machine learning (ML) implementation of the gradient boosting algorithm that is effective for predicting IC dies failures on bench tests according to examples disclosed herein. Evolving from the principles of gradient boosting, XGBoost incorporates a range of powerful enhancements that make XGBoost a highly efficient and effective tool for machine learning (ML) tasks. Key evolutionary features of XGBoost include regularization capabilities to prevent overfitting, support for parallel computation, and the ability to handle sparse data effectively. Additionally, XGBoost introduces sophisticated techniques such as tree pruning, handling missing values, and a novel sparsity-aware algorithm for finding optimal splits in trees. These enhancements make XGBoost faster, more scalable, and more accurate compared to traditional gradient boosting methods. The XGBoost models disclosed herein can, for example, be implemented by Python scripts that follow a comprehensive machine learning (ML) pipeline involving data preparation, model training, evaluation, and saving.

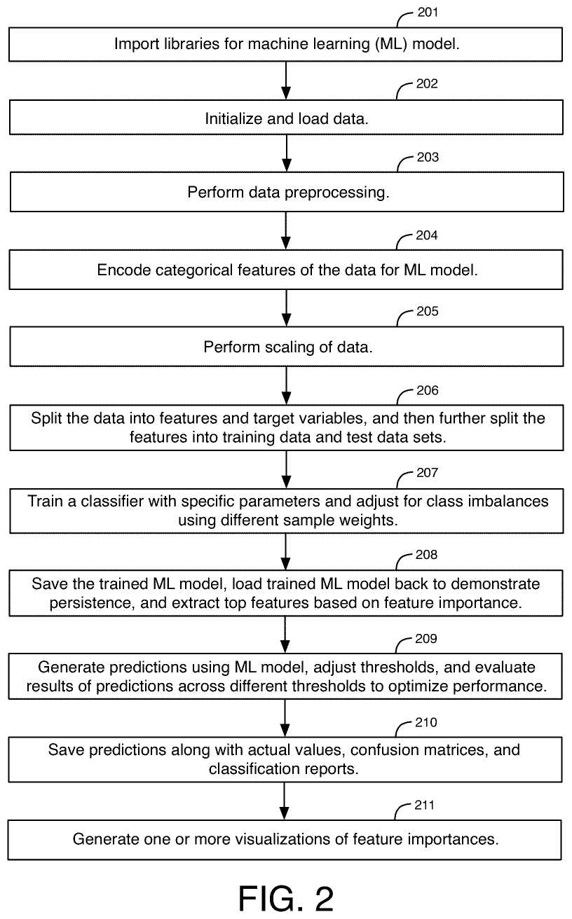

FIG. 2 is a diagram of a flow chart that includes examples of operations that can be performed to train an ML model for identifying failures in IC dies after manufacturing. The operations of Figure (FIG. 2 can, for example, be used to train each of the 6 XGBoost machine learning (ML) models disclosed herein above. Each of the 6 XGBoost ML models disclosed herein above can be implemented by a unique script.

In operation 201, libraries for one of the ML models are imported. As examples, the imported libraries can include pandas, shap, sklearn, xgboost, pickle, os, matplotlib, and numpy. In operation 202, data is initialized and loaded for the ML model. For example, large files of data can be loaded in chunks, concatenated, and then converted into a single file. The data initialized and loaded in operation 202 is the test data described above, including for example, test data using C2M, LR, and SR protocols. In operation 203, the data that was initialized and loaded in operation 202 is preprocessed. As an example, unnecessary columns and columns with only one unique value can be removed from the data in operation 203 to make the ML model more efficient by eliminating unneeded columns in which values are not changing.

In operation 204, categorical features of the data for the ML model that was preprocessed in operation 203 are encoded. For example, categorical string values in the data can be converted into numerical values using a Label Encoder function, if the ML model can only process numerical values.

In operation 205, the data for the ML model is scaled. As an example, the data for the ML model can be normalized between 0 and 1 using a MinMaxScaler function, and then the scaler object can be saved. Normalization is a data preprocessing technique utilized to standardize the values of features in a dataset, bringing the features to a common scale. This process enhances data analysis and modeling accuracy by mitigating the influence of varying scales on machine learning models. Normalization (i.e., min-max scaling) is a scaling technique in which values are shifted and rescaled so that the output values of the normalization range between 0 and 1. Equation (1) is a formula that can be used to normalize the values X′ in the data for the ML model.

$${X}^{′} = \frac{X - {X}_{MIN}}{{X}_{MAX} - {X}_{MIN}} \qquad ( 1 )$$

In operation 206, the data for the ML model is split into features (X) and target variables (Y). As examples, the features (X) can be multiple input columns in the data that were collected during testing, sorting, and classification of the IC dies, and the variables (Y) can be bench results for the IC dies that are output as a single output column. The bench results are test results that are generated during bench testing of the IC dies coupled to circuit boards, where the test results indicate whether the IC dies satisfy a manufacturing protocol. The bench results can be, as examples, for transceiver or serializer/deserializer (SERDES) links to IC dies. Also, in operation 206, the features (X) for the data for the ML model are then further split into training data and test data sets. As a specific example that is not intended to be limiting, 80% of the features (X) for the data for the ML model can be designated as training data for training the ML model, and 20% of the features (X) for the data for the ML model can be designated as test data for testing the trained ML model.

In operation 207, the ML model is trained. In operation 207, an ML model (e.g., XGBoost) classifier with specific parameters is trained and then adjusted for class imbalances using different sample weights. The ML model training performed in operation 207 involves comparing outputs of the ML model to bench results for the IC dies. Operation 207 includes the initialization of the ML model for training that determines how much depth the ML model needs to go through. If the ML model generates an imbalance of fails compared to passes in terms of the number of IC dies satisfying a manufacturing protocol, the sampling weights can be adjusted during training to balance the passing and failing results for the IC dies in operation 207. Sample weights are some of the parameters that are adjusted during training (e.g., of an XGBoost model) based on the amount of data used for training the ML model and the amount of fails in the IC dies identified by the ML model.

In operation 208, the trained ML model generated in operation 207 is saved (e.g., using a Python model pickle). The ML model is saved so that the ML model can be used on actual test data without having to train the ML model every time that the ML model is used. The trained ML model can, for example, be saved into a pickle file where the ML model can be loaded later to be used on actual test data to make predictions regarding whether the IC dies are passing or failing a manufacturing protocol. Then, the saved and trained ML model is loaded back to demonstrate persistence. Then, the top features of the trained ML model are extracted based on feature importance (e.g., using a feature extraction function in XGBoost). Feature importance determines which input parameters are most affecting the output of the ML model.

In operation 209, the ML model is used to generate predictions of which IC dies are passing and which IC dies are failing a manufacturing protocol in lots of manufactured IC dies. In operation 209, the thresholds of the ML model (e.g., XGBoost) can be adjusted to affect the predictions. Then, the results of the predictions can be evaluated across different thresholds to optimize performance. In operation 209, the ML model generates the predictions as outputs using the features (X) for the data for the ML model designated as test data in operation 206 without the bench results. Then, the outputs of the ML model (i.e., the predictions) are compared to the bench results for the IC dies to determine if the outputs of the ML model match the bench results to determine the capture rate of the ML model.

In operation 210, the predictions of the ML model are saved along with actual values, confusion matrices, and classification reports. The confusion matrices and classification reports can also be printed. In operation 210, the predictions provided as outputs of the ML model are evaluated to determine if the ML model predictions were performed correctly by generating the classification reports (e.g., in XBoost outputs).

In operation 211, one or more visualizations of the feature importance of the ML model are generated. As examples, feature importance can be visualized using matplotlib and XGBoost plotting functions. As additional examples, Python has multiple imported libraries that can generate plots that show the feature importance outputs of XGBoost.

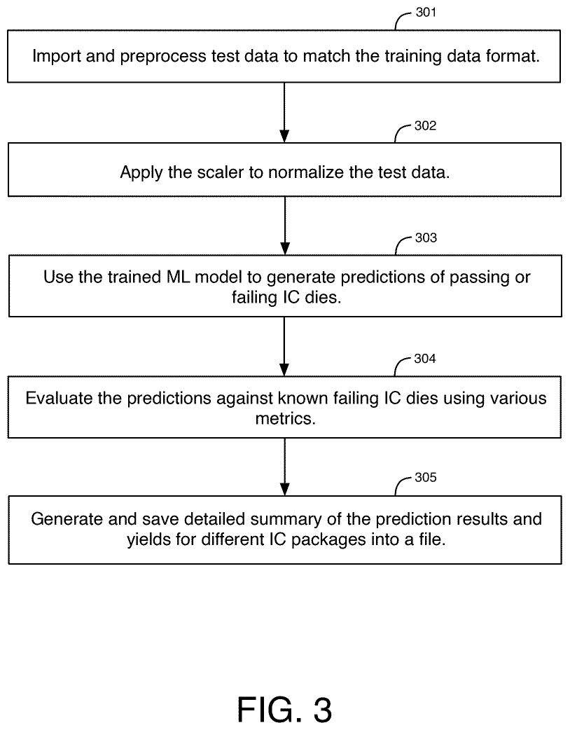

FIG. 3 is a diagram of a flow chart that includes examples of operations that can be performed to identify integrated circuit (IC) dies that fail to satisfy a manufacturing protocol using a trained ML model. The trained ML model used in the operations 301-305 of FIG. 3 can, for example, be trained and saved using the operations 201-211 of FIG. 2. In the operations of FIG. 3, the trained and saved ML model (e.g., an XGBoost model) processes actual test data from manufactured IC dies. The operations of FIG. 3 are performed using the trained ML model on actual test data that has no bench test results to compare to. A script (e.g., in Python) can implement operations 301-305 to process the actual test data using the trained ML model (e.g., an XGBoost model) and evaluate the performance of the ML model.

The operations of FIG. 3 can, for example, be implemented by 6 scripts for the 6 XGBoost models described above. In this example, the operations of FIG. 3 are run using each of the 6 XGBoost models one after the other. Thus, the operations of FIG. 3 are repeated 6 times for the 6 XGBoost models in this example.

In operation 301, actual test data generated from manufactured IC dies is imported and preprocessed to match the training data format. The actual test data can, for example, be encoded as disclosed above with respect to operation 204. In operation 302, a scaler is applied to normalize the actual test data. For example, the same scaler (e.g., disclosed above with respect to operation 205) that was used to normalize the test data during the ML model training can be used in operation 302. The actual test data is then provided to the ML model.

In operation 303, the trained ML model generated in operations 201-211 is loaded into a computer system (e.g., XGBoost model loaded from a pickle file), and then the trained ML model is used to generate predictions of which IC dies in a lot are failing and which IC dies in the lot are passing a manufacturing protocol (e.g., VSR, LR, or C2M). In operation 303, bench data for the IC dies is not available to compare to the predictions.

In operation 304, the predictions generated in operation 303 are evaluated against known failing IC dies using various metrics. The evaluation in operation 304 determines how many of the IC dies the ML model is predicting are failing and how many of the IC dies the ML model is predicting are passing the manufacturing protocol. In operation 305, a detailed summary of the prediction results from operations 303-304 and yields for different integrated circuit (IC) packages are generated and saved into a file.

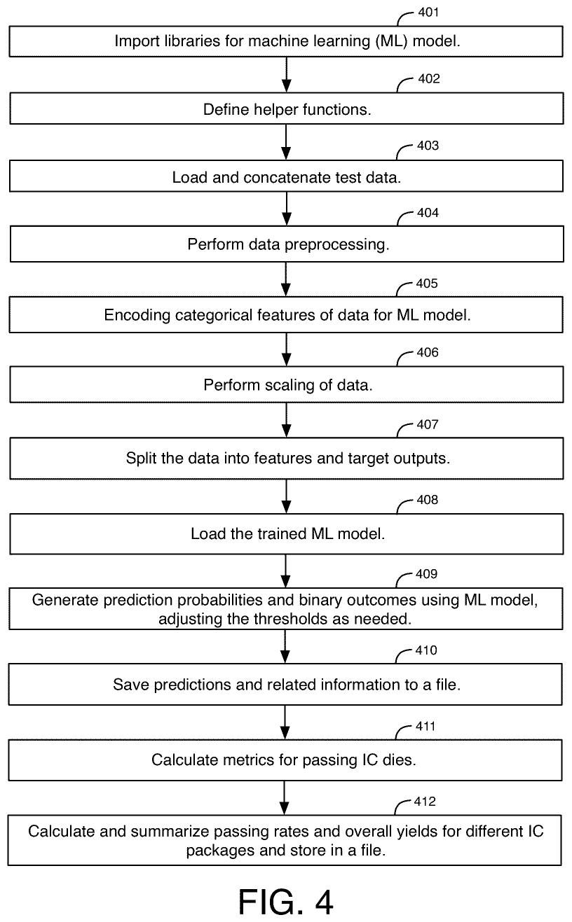

FIG. 4 is a diagram of another flow chart that includes examples of operations that can be performed to identify integrated circuit (IC) dies that fail to satisfy a manufacturing protocol using a trained ML model. The trained ML model used in the operations of FIG. 4 can, for example, be trained and saved using the operations 201-211 of FIG. 2. In the operations of FIG. 4, the trained and saved ML model (e.g., an XGBoost model) processes actual test data from manufactured IC dies that have no bench tests to compare to. The operations of FIG. 4 can be run for each of the 6 XGBoost models disclosed above in series.

In operation 401, libraries for the trained machine learning (ML) model are imported, such as the libraries disclosed above with respect to FIG. 2. In operation 402, helper functions are defined to compare list elements. The helper functions are used to determine if the actual test data has more parameters than the trained ML model is logging and not using. If the actual test data has more parameters than the trained ML model is using, then these extra parameters are removed at operation 402. Operation 402 can be implemented by comparing lists to ensure that the number of parameters is the same between the training and testing data sets.

In operation 403, the actual test data in large files is loaded and concatenated into a Data Frame file. In operation 404, data preprocessing is performed on the actual test data for the ML model. As an example, unnecessary columns in the actual test data can be removed, and conditional column operations can be processed in operation 404.

In operation 405, categorical features of the actual test data are encoded for the ML model. For example, categorical string values in the actual test data can be converted into numerical values using a Label Encoder function, if the ML model can only process numerical values, as discussed above with respect to operation 204.

In operation 406, the actual test data for the ML model is scaled using a scaler. For example, the actual test data for the ML model can be normalized between 0 and 1 using a MinMaxScaler function in operation 406, as disclosed above with respect to operation 205.

In operation 407, the actual test data is split into features (X) and target outputs (Y). The target outputs (Y) are not the bench results in operation 407, because bench results are not available for the actual test data. The target outputs (Y) in the actual test data are class results of the ML model. The target outputs (Y) indicate the failing results of the IC dies that a test program has indicated have failed the manufacturing protocol, and the target outputs (Y) are therefore removed from the actual test data at sort and class. The features (X) are test data for the IC dies that the test program has indicated have passed the manufacturing protocol (i.e., the passing results). In operation 407, the passing results are separated out from the failing results. Only the passing results for the IC dies are run through the ML model. Failing results for the IC dies are already screened by the test program.

In operation 408, the trained machine learning (ML) model (e.g., the trained XGBoost model) is loaded into a computer system (e.g., using pickle). The actual test data, including only the features (X) indicating the passing results that are separated out in operation 407, is then provided as input data to the ML model. In operation 409, the ML model running on the computer system generates prediction probabilities and binary outcomes indicating the passing and the failing IC dies, adjusting the thresholds as needed, as described above.

In operation 410, the predictions and related information are saved to a file. In operation 411, metrics are calculated for the passing IC dies. The metrics can be saved and printed. The metrics can include visual identifiers for the passing IC dies. In operation 412, passing rates and overall yields for different IC packages containing the IC dies are calculated, summarized, and then stored in a file.

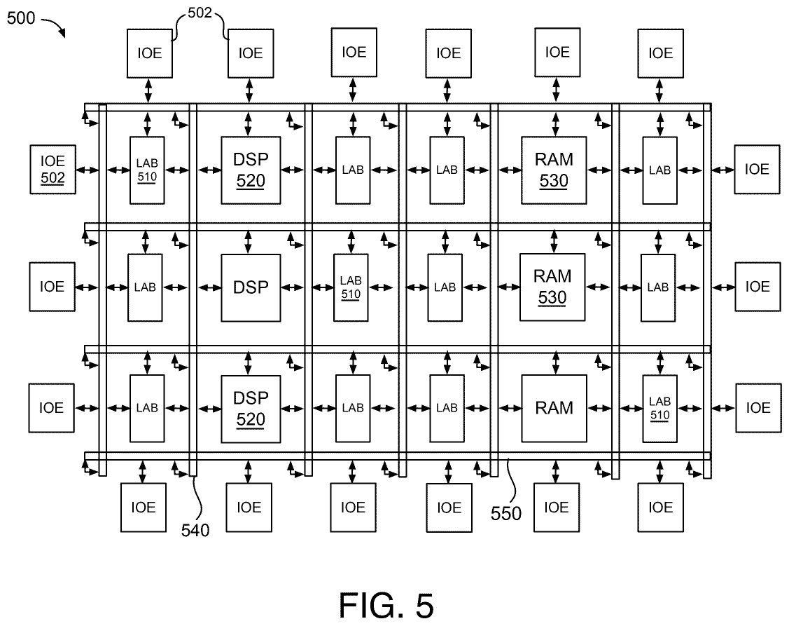

FIG. 5 is a diagram that illustrates an example of a configurable logic integrated circuit (IC) 500 that can, for example, be one or more of the IC dies tested using the operations disclosed herein with respect to FIGS. 1-4. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions and operations disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

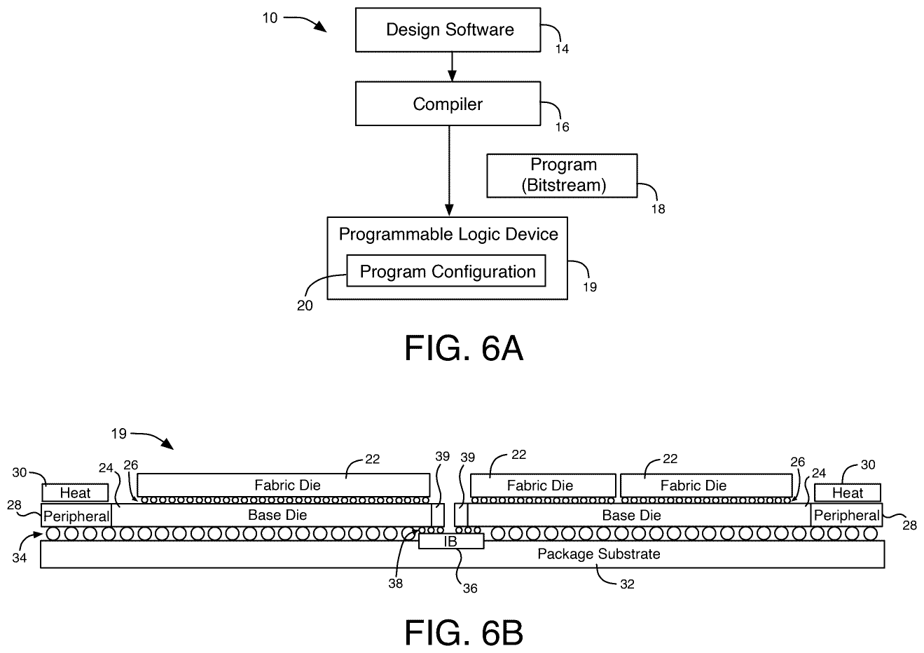

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

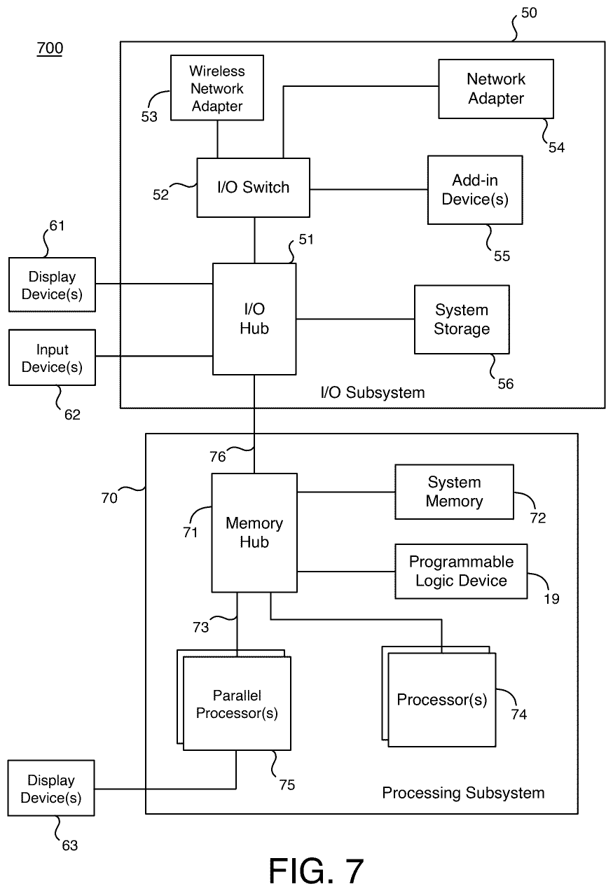

FIG. 7 is a block diagram illustrating a computing system 700 configured to implement one or more aspects of the embodiments described herein. The computing system 700 includes a processing subsystem 70 having one or more processor(s) 74 (e.g., processor integrated circuits), a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 (e.g., processor integrated circuits) coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

The computing system 700 is an example of a computing system that can implement the operations disclosed herein with respect to FIGS. 1-4. As examples, any one or more of parallel processors 75 (e.g., graphics processing units), processors 74, system memory 72, and/or programmable logic device 19 can implement the operations disclosed herein in any one or more of FIGS. 1, 2, 3, and/or 4.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is a computing system comprising: at least one processor circuit configured to receive first test data generated from testing integrated circuit dies in a test flow, wherein the computing system comprises a machine learning model that uses the first test data generated from the test flow to predict bench results that are indicative of which ones of the integrated circuit dies fail to satisfy a manufacturing protocol when the integrated circuit dies are coupled to circuit boards.

In Example 2, the computing system of Example 1 may optionally include, wherein the computing system uses the machine learning model to reduce defects in the integrated circuit dies coupled to the circuit boards.

In Example 3, the computing system of any one of Examples 1-2 may optionally include, wherein the computing system is further configured to encode second test data generated from testing the integrated circuit dies by converting categorical string values in the second test data into numerical values in the first test data.

In Example 4, the computing system of any one of Examples 1-3 may optionally include, wherein the computing system is further configured to scale second test data generated from testing the integrated circuit dies by normalizing the second test data to generate the first test data.

In Example 5, the computing system of any one of Examples 1˜4 may optionally include, wherein the computing system is further configured to determine if the first test data has more parameters than the machine learning model is using and to remove any of the parameters in the first test data that the machine learning model is not using.

In Example 6, the computing system of any one of Examples 1-5 may optionally include, wherein the bench results comprise transceiver or serializer/deserializer links.

In Example 7, the computing system of any one of Examples 1-6 may optionally include, wherein the computing system is further configured to adjust thresholds of the machine learning model to affect predictions of the bench results, and wherein the computing system is further configured to evaluate results of the predictions of the bench results across different ones of the thresholds to optimize performance of the machine learning model.

In Example 8, the computing system of any one of Examples 1-7 may optionally include, wherein the computing system is further configured to train the machine learning model to identify additional integrated circuit dies that fail to satisfy the manufacturing protocol using training data generated from the additional integrated circuit dies.

In Example 9, the computing system of any one of Examples 1-8 may optionally include, wherein the computing system is further configured to use an Extreme Gradient Boosting (XGBoost) model to predict the bench results.

Example 10 is a method for predicting if integrated circuit dies fail a manufacturing protocol, the method comprising: receiving first test data generated from testing the integrated circuit dies in a test flow at a computing system comprising at least one processor circuit; and using a machine learning model running on the computing system to generate predictions of bench results based on the first test data input to the machine learning model, wherein the bench results are indicative of which of the integrated circuit dies fail to satisfy the manufacturing protocol when the integrated circuit dies are coupled to circuit boards.

In Example 11, the method of Example 10 further comprises: using the machine learning model to reduce defects in the integrated circuit dies coupled to the circuit boards.

In Example 12, the method of any one of Examples 10-11 wherein the bench results comprise transceiver or serializer/deserializer links.

In Example 13, the method of any one of Examples 10-12 further comprises: adjusting thresholds of the machine learning model to affect the predictions using the computing system; and evaluating results of the predictions across different ones of the thresholds using the computing system to optimize performance of the machine learning model.

In Example 14, the method of any one of Examples 10-13 further comprises: scaling second test data generated from testing the integrated circuit dies by normalizing the second test data to generate the first test data.

In Example 15, the method of any one of Examples 10-14 may optionally include, wherein using the machine learning model running on the computing system to generate the predictions of the bench results further comprises using an Extreme Gradient Boosting (XGBoost) model running on the computing system to generate the predictions of the bench results.

Example 16 is a non-transitory computer readable storage medium comprising computer readable instructions stored thereon for causing a computing system to: receive training data generated based on testing first integrated circuit dies at the computing system comprising at least one processor circuit; train a machine learning model using the computing system by comparing outputs of the machine learning model generated with the training data to first bench results for the first integrated circuit dies, wherein the first bench results indicate the first integrated circuits dies that fail a manufacturing protocol when the first integrated circuit dies are coupled to first circuit boards; and generate predictions of second bench results for second integrated circuit dies using the machine learning model running on the computing system based on test data generated from testing the second integrated circuit dies, wherein the second bench results indicate the second integrated circuit dies that fail the manufacturing protocol when the second integrated circuit dies are coupled to second circuit boards.

In Example 17, the non-transitory computer readable storage medium of Example 16 may optionally include, wherein the computer readable instructions further cause the computing system to: adjust for class imbalances using different sample weights for the machine learning model using the computing system if the machine learning model generates an imbalance in the second integrated circuit dies that fail the manufacturing protocol compared to the second integrated circuit dies that pass the manufacturing protocol.

In Example 18, the non-transitory computer readable storage medium of any one of Examples 16-17 may optionally include, wherein the computer readable instructions further cause the computing system to: extract top features of the machine learning model using the computing system based on feature importance that indicates which input parameters to the machine learning model are most affecting the outputs of the machine learning model.

In Example 19, the non-transitory computer readable storage medium of any one of Examples 16-18 may optionally include, wherein the computer readable instructions further cause the computing system to: generate the predictions using features for the test data with the machine learning model without the second bench results; and compare the predictions to the second bench results for the second integrated circuit dies to determine if the predictions match the second bench results to generate a capture rate.

In Example 20, the non-transitory computer readable storage medium of any one of Examples 16-19 may optionally include, wherein the computer readable instructions further cause the computing system to: generate the predictions of the second bench results for the second integrated circuit dies that fail at least two manufacturing protocols based on the test data using the machine learning model, wherein the manufacturing protocols comprise at least two of Long Range, Very Short Range, and Chip-to-Module.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A computing system comprising:
at least one processor circuit configured to receive first test data generated from testing integrated circuit dies in a test flow, wherein the computing system comprises a machine learning model that uses the first test data generated from the test flow to predict bench results that are indicative of which ones of the integrated circuit dies fail to satisfy a manufacturing protocol when the integrated circuit dies are coupled to circuit boards.

2. The computing system of claim 1, wherein the computing system uses the machine learning model to reduce defects in the integrated circuit dies coupled to the circuit boards.

3. The computing system of claim 1, wherein the computing system is further configured to encode second test data generated from testing the integrated circuit dies by converting categorical string values in the second test data into numerical values in the first test data.

4. The computing system of claim 1, wherein the computing system is further configured to scale second test data generated from testing the integrated circuit dies by normalizing the second test data to generate the first test data.

5. The computing system of claim 1, wherein the computing system is further configured to determine if the first test data has more parameters than the machine learning model is using and to remove any of the parameters in the first test data that the machine learning model is not using.

6. The computing system of claim 1, wherein the bench results comprise transceiver or serializer/deserializer links.

7. The computing system of claim 1, wherein the computing system is further configured to adjust thresholds of the machine learning model to affect predictions of the bench results, and wherein the computing system is further configured to evaluate results of the predictions of the bench results across different ones of the thresholds to optimize performance of the machine learning model.

8. The computing system of claim 1, wherein the computing system is further configured to train the machine learning model to identify additional integrated circuit dies that fail to satisfy the manufacturing protocol using training data generated from the additional integrated circuit dies.

9. The computing system of claim 1, wherein the computing system is further configured to use an Extreme Gradient Boosting (XGBoost) model to predict the bench results.

10. A method for predicting if integrated circuit dies fail a manufacturing protocol, the method comprising:
receiving first test data generated from testing the integrated circuit dies in a test flow at a computing system comprising at least one processor circuit; and
using a machine learning model running on the computing system to generate predictions of bench results based on the first test data input to the machine learning model, wherein the bench results are indicative of which of the integrated circuit dies fail to satisfy the manufacturing protocol when the integrated circuit dies are coupled to circuit boards.

11. The method of claim 10 further comprising:
using the machine learning model to reduce defects in the integrated circuit dies coupled to the circuit boards.

12. The method of claim 10, wherein the bench results comprise transceiver or serializer/deserializer links.

13. The method of claim 10 further comprising:
adjusting thresholds of the machine learning model to affect the predictions using the computing system; and
evaluating results of the predictions across different ones of the thresholds using the computing system to optimize performance of the machine learning model.

14. The method of claim 10 further comprising:
scaling second test data generated from testing the integrated circuit dies by normalizing the second test data to generate the first test data.

15. The method of claim 10, wherein using the machine learning model running on the computing system to generate the predictions of the bench results further comprises using an Extreme Gradient Boosting (XGBoost) model running on the computing system to generate the predictions of the bench results.

16. A non-transitory computer readable storage medium comprising computer readable instructions stored thereon for causing a computing system to:
receive training data generated based on testing first integrated circuit dies at the computing system comprising at least one processor circuit;
train a machine learning model using the computing system by comparing outputs of the machine learning model generated with the training data to first bench results for the first integrated circuit dies, wherein the first bench results indicate the first integrated circuits dies that fail a manufacturing protocol when the first integrated circuit dies are coupled to first circuit boards; and
generate predictions of second bench results for second integrated circuit dies using the machine learning model running on the computing system based on test data generated from testing the second integrated circuit dies, wherein the second bench results indicate the second integrated circuit dies that fail the manufacturing protocol when the second integrated circuit dies are coupled to second circuit boards.

17. The non-transitory computer readable storage medium of claim 16, wherein the computer readable instructions further cause the computing system to:
adjust for class imbalances using different sample weights for the machine learning model using the computing system if the machine learning model generates an imbalance in the second integrated circuit dies that fail the manufacturing protocol compared to the second integrated circuit dies that pass the manufacturing protocol.

18. The non-transitory computer readable storage medium of claim 16, wherein the computer readable instructions further cause the computing system to:
extract top features of the machine learning model using the computing system based on feature importance that indicates which input parameters to the machine learning model are most affecting the outputs of the machine learning model.

19. The non-transitory computer readable storage medium of claim 16, wherein the computer readable instructions further cause the computing system to:
generate the predictions using features for the test data with the machine learning model without the second bench results; and
compare the predictions to the second bench results for the second integrated circuit dies to determine if the predictions match the second bench results to generate a capture rate.

20. The non-transitory computer readable storage medium of claim 16, wherein the computer readable instructions further cause the computing system to:
generate the predictions of the second bench results for the second integrated circuit dies that fail at least two manufacturing protocols based on the test data using the machine learning model, wherein the manufacturing protocols comprise at least two of Long Range, Very Short Range, and Chip-to-Module.
